(19) United States
(12) Patent Application Publication
(10) Pub. No.: US 2017/0261541 A1
(43) Pub. Date: Sep. 14, 2017

(54) GROUND FAULT DETECTOR AND METHOD FOR DETECTING GROUND FAULTS

(71) Applicant: Otis Elevator Company, Farmington, CT (US)

(72) Inventor: Peter Herkel, Berlin (DE)

(21) Appl. No.: 15/509,708

(22) PCT Filed: Sep. 12, 2014
(86) PCT No.: PCT/EP2014/069566

§ 371 Date: Mar. 8, 2017

(51) Int. Cl. G01R 31/02

(52) U.S. Cl. CPC G01R 31/025

(57) ABSTRACT

A ground fault detector circuit (140) for a people conveyor configured to detect a ground fault in a safety chain (100) of the people conveyor, comprises a first resistor (130) connected between a first contact (P1) on the supply (126) of the safety chain (100) and a second contact (P2) on the return (122) of the safety chain (100), and a device (134) for detecting a change in voltage drop (UGFD) with respect to ground across said first resistor (130).

The present invention relates to a ground fault detector, particularly for a people conveyor like an elevator, an escalator or a moving walkway. The present invention also relates to a method of detecting such ground fault, particularly considering ground fault resistance.

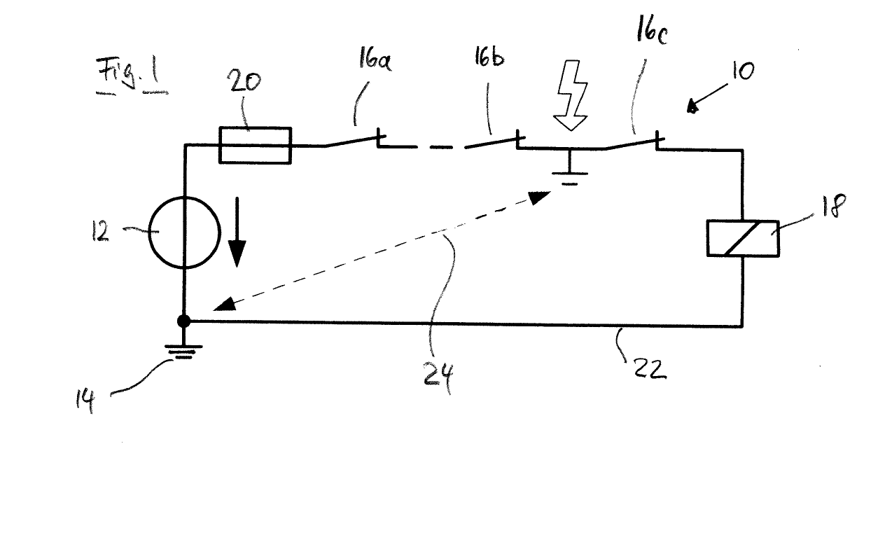

A ground fault is an unwanted connection in an electrical circuit to ground or earth. Ground fault detection is a required function for the safety circuit or safety chain in people conveyors, as specified e.g. in any elevator safety code worldwide. Currently, ground fault is detected by a fuse. As shown in FIG. 1, a safety chain 10 is connected between power supply 12 and ground or earth 14. The safety chain 10 includes a number of safety switches 16a, 16b, 16c and a safety relay 18, all connected in series. A fuse 20 is connected in series with the safety chain 10 and the safety chain return 22, as shown in FIG. 1. The safety chain return 22 is connected to ground 14. When any point in the wiring of the safety chain 10 has contact to ground, as indicated by the dashed line 24 in FIG. 1, current flowing through fuse 20 will increase the current threshold of fuse 20 and fuse 20 will blow.

Implementation of ground fault detection using a fuse 20 as shown in FIG. 1 requires that, in case a ground fault occurs, power supply 12 is able to provide sufficient current to blow the fuse 20 within a threshold time. For example, EN 60204-1 specifies a threshold time of 5 s for blowing the fuse in case of a ground fault. To safely trigger the fuse within 5 s, as requested by safety code requirements, current flowing through the fuse must exceed the threefold of the nominal current threshold of the fuse. Standard transformers, as conventionally used for power supply in elevators, are able to deliver sufficiently high currents. However, switching-mode power supplies, as used more and more instead of transformers, usually have a current limitation and therefore may not be able to supply sufficient electric current to blow the fuse in case of a ground fault, or need to be overdimensioned in order to be able to safely blow the fuse in case of a ground fault. For example, in the safety chain shown in FIG. 1, in normal condition a current of 0.16 A is flowing in the safety chain at a safety chain supply voltage of 48 V DC. The rated current threshold for triggering the fuse 20 is 0.4 A, i.e. the fuse will not blow in case the current stays below this rated current threshold. In this example, to blow the fuse 20 within 5 s, current in the safety chain must exceed 1.2 A. Therefore, any power supply used as supply for the safety chain must be able to provide a power of 48 V DC times 1.2 A=58 W. However, in normal conditions only a power of 8 W is required. Therefore, the power supply must be significantly overdimensioned with respect normal operation requirements, in order to meet the safety code requirements with respect to ground fault protection.

A further requirement for a fuse 20 to safely blow in case of a ground fault is that the load of the safety relay 18 connected to the safety chain 10 should be relatively high. This implies that the safety relay 18 should have a low coil resistance. While conventionally used electro-mechanical relays/contactors do generally fulfil this requirement, such electro-mechanical relays/contactors are more and more replaced by semiconductor switches based on printed circuit relays which have much higher coil resistance (about 2300 Ohm compared to about 300 Ohm for an electro-mechanical relay/contactor). Moreover, the resistance of the ground fault should be low compared to the resistance of the load.

The schematic of FIG. 1 indicates a ground fault 24 occurring somewhere in the middle of the safety chain 10. With a hard ground fault, ground resistance will be less than 1 Ohm and the current flowing through the fuse 20 will increase to above 4 A. This will lead to blowing of the fuse. However, with soft ground fault, e.g. at a ground fault resistance in the order of 100 Ohm, existence of the ground fault will increase the current flowing through the fuse 20 in the order of its trigger current (e.g. 0.4 A) only. Although this is above the current threshold of 0.4 A for triggering the fuse 20, it will take much more time than 5 s to blow the fuse 20. Typically, in this example, the fuse 20 may take several minutes to blow. As a consequence, a soft ground fault as described above might be detected late or even not be detected at all, contrary to code requirements. In case a second ground fault occurs later both ground faults together may lead to a safety issue under certain conditions. The probability of such problems even increases where printed circuit board relays are used instead of relays/contactors, since printed circuit board relays have a higher coil resistance than mechanical contactors/relays.

It would be beneficial to overcome the above mentioned problems, in particular to be able to detect ground faults and provide safety measures with respect to ground faults and to be able to safely detect even soft ground faults and/or requiring less overdimensioning of the power supply.

Embodiments disclosed herein relate to a circuit and method for detecting a ground fault, particularly considering ground fault resistance, in a safety chain circuit, particular in a safety chain circuit of a people conveyor like an elevator, escalator and/or moving walkway.

A ground fault detector circuit for a people conveyor configured to detect a ground fault in a safety chain of the people conveyor, according to one embodiment comprises: a first resistor connected between a first contact on the supply side of the safety chain and a second contact on the ground side of the safety chain, and a device for detecting a change in voltage drop UGFD across said first resistor.

A method for detecting a ground fault in a safety chain of a people conveyor, according to a further embodiment, comprises: detecting a change in voltage drop across a first resistor connected between a first contact on the supply side of the safety chain and a second contact on the ground side of the safety chain.

Particular embodiments of the invention will be described in detail below with reference to the enclosed figure, wherein:

FIG. 1 shows a circuit diagram of a safety chain including a fuse for ground fault detection according to the prior art.

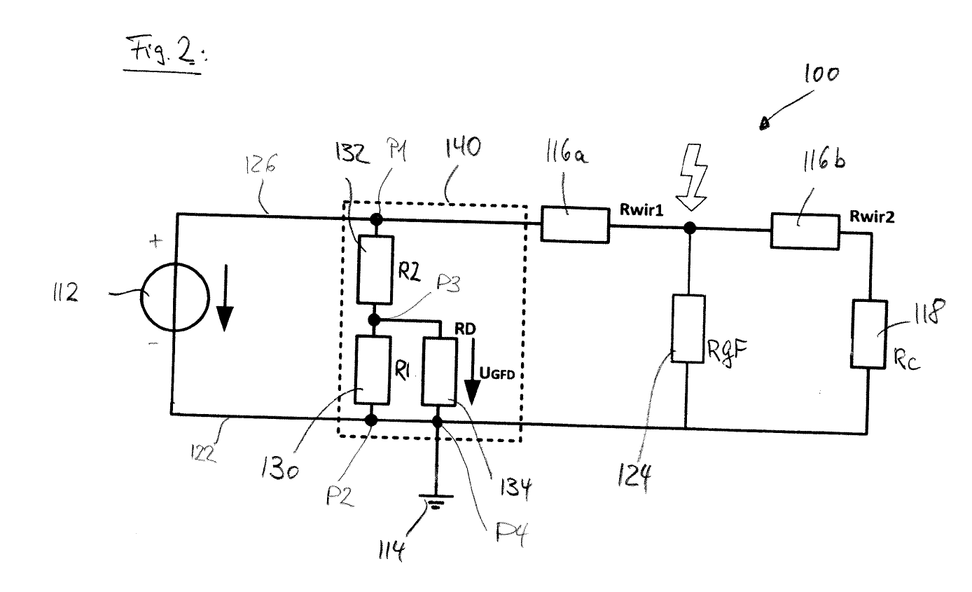

FIG. 2 shows a circuit diagram of a safety chain including a ground fault detector circuit according to a first embodiment.

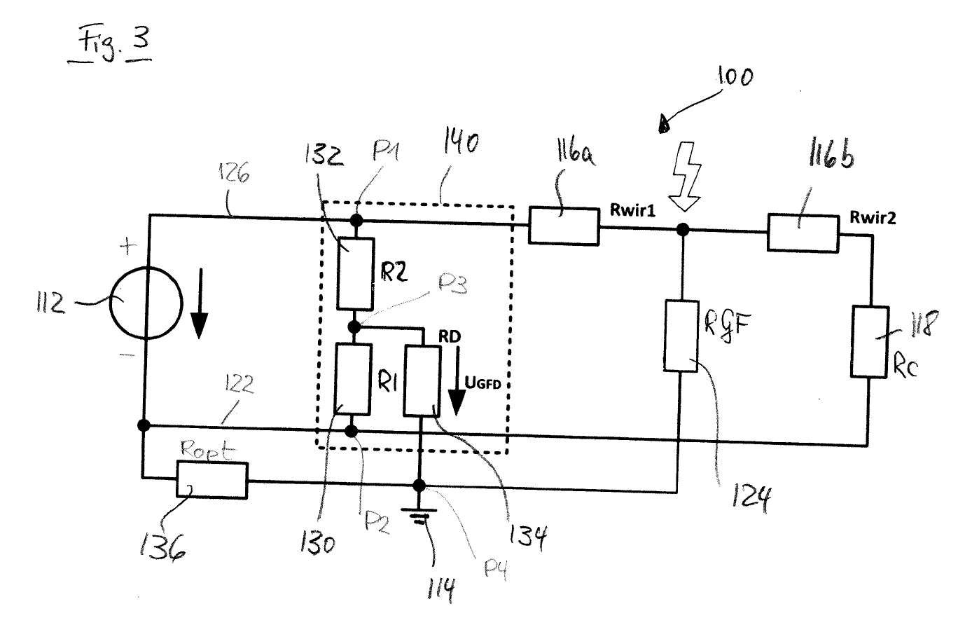

FIG. 3 shows a circuit diagram of safety chain including a ground fault detector circuit according to another embodiment.

FIG. 2 shows a safety chain 100 including a ground fault detector circuit 140 according to an exemplary embodiment of the invention. FIG. 3 shows a safety chain 100 including a ground fault detector circuit 140 according to a further exemplary embodiment of the invention. Ground fault detector 140 is used to detect an unwanted connection in safety chain 100 ground or earth 114. The embodiments of FIGS. 2 and 3 differ from each other in that in the embodiment of FIG. 2 the safety chain return 122 connecting the safety relay 118 to the negative pole of voltage supply 112 is connected to ground 114 and thus is at ground or earth potential, whereas in the embodiment of FIG. 3 the safety chain return 122 is connected to ground 114 via an additional resistor 136 having a resistance Ropt (this additional resistor 136 will be referred to as fourth resistor in the following) and therefore is at a higher electrical potential than electrical potential of ground 114.

The ground fault detector circuits 140 of FIGS. 2 and 3 are identical to each other, except for the fact that in the embodiment of FIG. 2 the first resistor 130 having a resistance R1 and the negative pole of voltage supply 112 are connected directly to ground 114 , whereas in FIG. 3 the first resistor 130 and the negative pole of the voltage supply 112 are connected to ground 114 via fourth resistor 136 having a resistance Ropt. The first resistor 130 in FIG. 3 therefore has its downstream end on an electrical potential larger than the electrical potential of ground 114 by the voltage drop across the fourth resistor 136. In the embodiments according to both FIGS. 2 and 3, a detecting resistor 134 having a resistance RD is connected in parallel to the first resistor 130 between the upstream end of the first resistor 130 and ground 114. In FIG. 2 safety chain return 122 is connected to ground 114, and therefore, in the embodiment of FIG. 2, the detecting resistor 134 detects the voltage drop UGFD across the first resistor 130 with respect to the electrical potential of ground 114 directly. In contrast, in the embodiment of FIG. 3, the detecting resistor 134 detects the voltage drop UGFD across the first resistor 130 plus the voltage drop across the fourth resistor 136 with respect to the electrical potential of ground 114.

Otherwise, the embodiments shown in FIGS. 2 and 3 provide the same technical teaching. Therefore, the same reference signs are used in FIGS. 2 and 3 for the same components. Description of such components will be given with respect to FIG. 2 only, it be understood that the same description will also apply to the corresponding components shown in FIG. 3.

As shown in FIGS. 2 and 3, safety chain 100 is connected between positive and negative poles of a DC power supply 112. As mentioned above, in FIG. 2 negative pole of power supply 112 and safety chain return 122 connecting the safety chain 100 to the negative pole of power supply 112 are at the electrical potential of ground 114, while in the FIG. 3 the negative pole of power supply 112 and the safety chain return 122 are at a larger electric potential than the electric potential of ground 114. In FIGS. 2 and 3, safety chain 100 includes a number of safety switches 116a, 116b and a safety relay 118, all connected in series. In FIGS. 2 and 3, safety switches 116a, 116b, and safety relay 118 are shown as an equivalent electrical resistance Rwir1, Rwir2, Rc, respectively.

Rwir1 represents the electrical resistance of the safety chain section including first safety switch 116a. Rwir2 represents the electrical resistance of the safety chain section including second safety switch 116b, etc. Rc represents the electrical resistance (coil resistance) of the safety chain section including first safety relay 118. Instead of connecting a fuse in series with the safety chain 10 (as shown in FIG. 1), the safety chain 100 includes a ground fault detector circuit 140. In FIGS. 2 and 3, a ground fault is indicated by way of an equivalent resistor 124 of the ground fault having a resistance RGF, such resistor 124 being connected in between a first contact somewhere in the safety chain (usually on the upstream side of any of the safety chain switches 116a, 116b, or of the safety chain relay 118, depending on the location where the ground fault occurs) and ground 114. Resistor 124 indicates that any point in the wiring of the safety chain 100 has contact to ground 114 other via the safety chain return 122, thereby providing an electrically conductive connection to ground 114 having some electric resistance (in case of a soft ground fault where ground fault resistance RGF still is in the order of several Ohm to several hundred Ohm), or even short circuiting current in safety chain 100 (in case of a hard ground fault where ground fault resistance RGF is essentially zero or a few Ohm at most).

According to the embodiments shown in FIGS. 2 and 3, ground fault resistance RGF is detected by a ground fault detector circuit 140. Ground fault detector circuit 140 essentially is formed by a network of Resistors. The network comprises three resistors 130, 132, and 134. In FIG. 3, besides the network formed by resistors 130, 132, and 134, and additional resistor 136 is connected in between the negative pole of the power supply 112 and ground 114 such that the safety chain return 122 is a larger electric potential than ground 114. In FIGS. 1 and 2, first resistor 130 having resistance R1 and second resistor 132 having a resistance R2 are connected in series to each other and form a voltage divider connected between a safety chain supply 126 and safety chain return 122. Third resistor 134 is a detecting resistor used to detect the voltage drop UGFD across first resistor 130 with respect to ground 114. In the embodiment of FIG. 2, third resistor 134 detects the voltage drop UGFD across first resistor 130 with respect to ground 114. In the embodiment of FIG. 3, third resistor 134 detects the voltage drop UGFD across first resistor 130 and fourth resistor 136 with respect to ground 114. Therefore, in FIGS. 2 and 3 the detecting resistor 134 is connected in parallel to first resistor 130. In the embodiment shown in FIG. 2, both the first resistor 130 and the detecting resistor 134 are connected directly to ground 114, and thus the voltage UGFD detected by detecting resistor 134 is identical to voltage drop across first resistor 130 of the voltage divider with respect to ground 114 In the embodiment of FIG. 3, detecting resistor 134 is connected to ground 114 directly, whereas the fourth resistor 136 is connected in between first resistor 130 and ground 114. Therefore, in the embodiment of FIG. 3, the voltage UGFD detected by third resistor 134 is not identical to the voltage drop across the first resistor 130 with respect to ground 114, but is identical to the voltage drop across both the first resistor 130 and fourth resistor 136 with respect to ground 114, i.e. UGFD =U0×(R1+Ropt)/(R1+R2+Ropt). Here, U0 is the nominal voltage of the power supply in case no ground fault exists. As Ropt is not affected by any changes in the ground fault resistance RGF, also in the embodiment of FIG. 3, UGFD is a direct measure of the change in voltage drop across first resistor 130, thus of the electrical resistance RGF of a ground fault 124. In both embodiments according to FIG. 2 and FIG. 3 the voltage UGFD detected by detecting resistor 134 will become lower in case a ground fault 124 occurs somewhere in the safety chain, such that ground fault resistance RGF becomes smaller than infinity. The smaller ground fault resistance RGF is, the smaller will become UGFD. UGFD will be a measure of the total electrical resistance of all ground faults 124 occurring in the safety chain at a given time.

In the embodiment shown in FIG. 2, a power supply having a nominal voltage rating larger than a minimum threshold is required to allow correct functioning of the safety chain (e.g. for a nominal voltage of 48 V and a nominal load of 288 Ohm a power supply capable to able to provide 8 W is required). A lower power supply might lead to problems with the correct functioning of the safety chain, particularly the safety relay might not activate properly. Moreover, in the embodiment of FIG. 2 a current limitation in the power supply 112 is required to be able to detect the resistance RGF of a ground fault. For example, the power supply may be restricted to deliver a maximum power of a percentage of the nominal power in order to safely detect any ground fault which will affect the drop-out of the safety relay 118. A typical current limitation might limit the power deliverable by the power supply to about 150% of its nominal power, particularly to about 125% of its nominal power, or even lower. Within this limit the ground fault detector circuit 140 will either detect any ground fault or the ground fault will be soft enough (i.e. have a resistance high enough) that the remaining voltage over the safety relay 118 will decrease below the minimum drop-out voltage of the safety relay 118.

For the embodiment of FIG. 3 due to the presence of the fourth resistor 136 having the resistance Ropt, there is no specific requirement for the minimum nominal power of the voltage supply 112 and the resistance RGF of any ground fault can be measured by detecting the value of UGFD.

In FIGS. 2 and 3, the electrical resistance of any of the safety switches 116a, 116b, is represented by an equivalent resistance Rwir1, Rwir2 of the respective wire section in the safety chain 100, since the resistance of a safety switch as such should be close to zero, unless the safety switch has been opened in case of a failure occurring in the safety chain.

Moreover, in the embodiments of FIGS. 2 and 3, electrical fuse 20 as conventionally used for ground fault detection and protection has been replaced by resistor network 140 adapted to detect a change in voltage drop across first resistor 130 with respect to ground 114 in cause of a ground fault 124 occurring in the safety chain 100.

In case presence of a ground fault is detected by the ground fault detector circuit 140 according to any embodiment described herein, the ground fault detector circuit 140 will shut down the power supply 112.

Embodiments as described above provide for a ground fault detector circuit for a people conveyor configured to detect a ground fault in a safety chain of the people conveyor. One embodiment comprises: a first resistor connected between a first contact on the supply of the safety chain and a second contact on the return of the safety chain, and a device for detecting a change in voltage drop across said first resistor with respect to ground. The voltage drop across the first resistor with respect to ground detected depends on the electrical resistance of any ground fault occurring in the safety chain. The change in voltage drop across the first resistor with respect to ground is a function of the ground fault resistance. The lower the ground fault resistance the lower the voltage drop across the first resistor will be in relation to the voltage drop across the first resistor without a ground fault, i.e. with ground fault resistance being infinity. Particularly, the first contact may be located on the supply side end or upstream end of the safety chain as close as appropriate to the power supply of the safety chain, particularly upstream of any of the first of the safety switches in the safety chain and the safety relay. Particularly, the second contact may be located on the return side end or downstream end of the safety chain as close as appropriate to the power supply of the safety chain, particularly downstream of any of the safety switches in the safety chain and the safety relay. The supply side of the safety chain may be the section upstream of the safety switches in the safety chain. The return side of the safety chain may be the section downstream of the safety switches in the safety chain. The terms “upstream”/“supply side”, as used herein, refer to the conventional current direction, i.e. referring to the positive polarity in case of a DC voltage source. Consequently, the terms “downstream” or “ground side” refer to the negative polarity in case of a DC voltage source. Throughout this disclosure, the term “ground” or “earth” is used to designate the electrical connection to the potential of earth, while the term “return” is used to designate the electrical connection to the common electric reference potential in the safety chain (typically the electric potential of the negative pole of the power supply).

In particular embodiments, the ground fault detector may include any of the following optional features. Unless specified to the contrary, these optional features may be combined with the above embodiment and with each other, or may be included in the above embodiment in isolation from other optional features.

The ground fault detector circuit further may comprise a network of resistors including at least the first resistor and a second resistor connected in series between the first contact on the supply of the safety chain and the second contact on the return of the safety chain. The network of resistors therefore may provide for a voltage divider connected between the safety chain supply and a the safety chain return. The change in voltage drop may be measured across the downstream resistor of the voltage divider, i.e. the voltage divider may include a first resistor connected to a second resistor at its upstream side and connected to the safety chain return at its downstream side. The second resistor in such voltage divider will be connected to the safety chain supply on its upstream side and to the first resistor on its downstream side. The change in voltage drop across the first resistor with respect to ground may be detected by a third resistor connected in parallel to the first resistor in between the supply side of the safety chain and ground or earth.

The electrical resistances R1, R2 of the first and second resistors may be adjusted as appropriate. Usually, the ratio of the electrical resistance R1 of the first resistor and the electrical resistance R2 of the second resistor will be adjusted such that R1/R2 times the supply voltage U0 delivered by the voltage source leads to a voltage drop across the first resistor of UGFD=R1/(R1+R2)×U0 that may be conveniently measured (in case no ground fault is present). In case of a ground fault, UGFD will become lower than R1/(R1+R2)×U0, depending on the electrical resistance of the ground fault. The lower the electrical resistance of the ground fault, the lower will become UGFD. In case of a ground fault short circuiting the safety chain, UGFD will break down.

For detecting the change in voltage drop UGFD across the first resistor with respect to ground, a third resistor (which also may referred to as a detecting resistor) may be connected in parallel to the first resistor. The third resistor does not necessarily need to be a single resistor, but may also have the configuration of a more complex detecting circuit as used in the art for detecting a voltage. In such cases, the voltage detecting circuit typically will be assigned to an equivalent intrinsic resistance RD which will be referred to as the resistance of the third or detecting resistor. As the third or detecting resistor basically is a voltage measurement device, the electrical resistance RD of the third or detecting resistor typically will be set to a large value compared to the resistance R1 of the first resistor, and compared to the resistances R1, R2 of both the first and second resistors in embodiments comprising a voltage divider formed by the first and second resistor. The detecting resistor may be connected between a third contact at the upstream end of the first resistor and a fourth contact at ground.

In one embodiment, the resistance network may include at least three resistors, two of the resistors connected in series between the first and second contact points to form a voltage divider, and the third resistor being the detecting resistor connected in parallel to the first resistor, in order to detect the change in voltage drop UFGD with respect to ground across the first resistor.

The ground fault detector circuit may be adapted such as to work for safety chain embodiments where the electrical potential of the safety chain return is larger than the electric potential of ground or earth. Typically, such embodiments may be considered as including an optional fourth resistor Ropt connected in between the safety chain return and ground. Then, the third transistor used to detect the voltage drop across the first resistor with respect to ground may be connected in parallel to the first resistor in between the upstream side of the first resistor and ground.

The change in voltage drop UGFD across the first resistor depends on the resistances in the safety chain circuit as follows: The most significant impact on a change in UGFD has the occurrence of a ground fault resistance smaller than infinity, with UGFD=R1/(R1+R2)×U0 in case of the ground fault resistance RGF being infinity (i.e. no ground fault is occurring), and UGFD=0 in case of existence of an extremely hard ground fault having a ground fault resistance RGF of zero. Here, U0 is the nominal voltage of the power supply. In embodiments where the electrical potential of the safety chain return is larger than ground potential, i.e. where an additional fourth resistor Ropt is connected between the safety chain return and ground, as set out above, the absolute value of UGFD will be determined also by Ropt. Ropt does not change in case of occurrence of a ground fault, and therefore Ropt does not have an influence neither on the direction nor on the relative value of change of UGFD when a ground fault resistance RGF smaller than infinity occurs. The absolute values of the resistances R1, R2, RD of the first resistor, second resistor, and the third resistor, respectively, may have some influence on the absolute value of UGFD, but do not affect the change of UGFD with occurrence of a ground fault resistance RGF smaller than infinity. Therefore, these resistances do not disturb detection of ground fault resistance. An even minor, and thus negligible, impact on the absolute value of UGFD do have the resistances Rwir1, Rwir2; . . . of the wiring in the safety chain sections between the safety switches, as well as the coil resistance Rc of the safety chain relay.

Therefore, ground fault resistance RGF in the safety chain can be calculated by detecting the change in voltage drop UFGD across the first resistor with respect to ground. The detection algorithm can be implemented in software or hardware. In particular embodiments, the ground fault detector circuit further may comprise a microprocessor for evaluation the voltage drop across the resistor.

The ground fault detector circuit as described herein is able to detect a ground fault principally unaffected by the coil resistance Rc of the safety chain relay. Therefore, the safety chain may include a safety relay having a coil resistance of 1000 Ohm, or larger, e.g of 2300 Ohm without affecting the reliability of detection of a ground fault.

Moreover, the ground fault detecting circuit according to particular embodiments may have any of the following characteristics, alone or in combination: The ground fault detecting circuit may be applicable for ground fault detection with non-activated safety chain relay, but also with activated safety chain relay. Moreover, the ground fault detecting circuit is able to detect a ground fault basically independent of the coil resistance of the safety chain relays.

In some embodiments the ground fault detector circuit may be adapted or configured to carry out a ground fault test continuously, or quasi-continuously, over time, i.e. the voltage drop UGFD is monitored continuously, or quasi-continuously over time, and any time a change in voltage drop UGFD outside a predetermined corridor is detected, it is determined that a ground fault has occurred. Different consequences may be provided depending on the amount of change of the voltage drop UGFD across the first resistor. Particularly, in case presence of a ground fault is detected by the ground fault detector circuit according to any embodiment described herein, the ground fault detector circuit may trigger a shut-down of the power supply.

It may further be possible to configure the ground fault detector circuit in such a way as to carry out a ground fault test at discrete points in time. This can be implemented relatively elegantly by a microprocessor controlling operation of the safety chain circuit. Such microprocessor may carry out a routine for detecting the voltage drop across the first resistor in particular time intervals, and may particularly also control operation of other devices in the safety chain, e.g. operation of the safety relays. A ground fault test may be performed automatically, e.g. by a respective routine in the microprocessor, and/or may be carried out “manually”, i.e. on demand by a person entering a command, typically such person will be a service person.

The ground fault detector circuit further may be adapted to determine a “dangerous” ground fault in case the change in voltage drop UGFD across the first resistor with respect to ground is equal to, or larger, than a first threshold value.

Particularly in such cases, the ground fault detector circuit will trigger a shutdown of the power supply. In other cases, particular in cases where the change in voltage drop UGFD is equal to, or lower, than a second threshold value, the ground fault detector circuit further may be adapted to determine a “tolerable” ground fault, i.e. a ground fault with a ground fault resistance high enough to avoid overcurrents, and thus not requiring an immediate shut off of the passenger conveyor. In particular, the second threshold value for determining a tolerable ground fault may be equal to the first threshold value. In particular embodiments, the first and second threshold values can be adjusted in the software that detects the voltage drop UGFD.

In further particular embodiments, the ground fault detector circuit as suggested herein further may include a power supply unit having a rated power corresponding to nominal power times rated current in the safety chain. As the ground fault is detected by a change in voltage drop across the first resistor with respect to ground, it is not necessary that a large current flows in the sections of the safety chain in between the ground fault and the voltage source. For the same reason, the ground fault detecting circuit as suggested herein is able to successfully operate with a reduced supply voltage. Thereby, high currents can be avoided that would otherwise occur during tests in case of ground fault.

As is evident from the paragraphs above, herein also a method for detecting a ground fault in a safety chain of a people conveyor is described. Particularly, such method includes: Detecting a change in voltage drop UGFD with respect to ground across a first electrical resistor connected between a first contact on the supply side of the safety chain and a second contact on the return side of the safety chain. The method may also include any other step as described above with respect to a ground fault detector circuit.

1. A ground fault detector circuit (140) for a people conveyor configured to detect a ground fault in a safety chain (100) of the people conveyor, comprising:
a first resistor (130) connected between a first contact (P1) on the supply (126) of the safety chain (100) and a second contact (P2) on the return (122) of the safety chain (100), and a device for detecting a change in voltage drop (UGFD) across said first resistor (130) with respect to ground (114).

2. The ground fault detector circuit (140) according to claim 1, further comprising a network including at least the first electrical resistor (130) and a second resistor (132) connected in series between the first contact (P1) on the supply (126) of the safety chain (100) and the second contact (P2) on the return(122) of the safety chain (100).

3. The ground fault detector circuit (140) according to claim 1, wherein the device (134) for detecting a change in voltage drop (UGFD) across said first resistor (130) with respect to ground (114) is a third resistor (134) that is connected in parallel to the first resistor (132) for detecting the change in voltage drop across the first resistor (130) with respect to ground (114).

4. The ground fault detector circuit (140) according to claim 3, wherein the third resistor (134) is connected between a third contact (P3) upstream of the first resistor (130) and a fourth contact (P4) at ground (114).

5. The ground fault detector circuit (140) according to claim 1, wherein the second contact (P2) is connected downstream of a safety chain relay (118).

6. The ground fault detector circuit (140) according to claim 1, wherein the return (122) of the safety chain is at an electrical potential larger than the electrical potential of ground (114), and wherein the third resistor (134) is connected in parallel to the first resistor and to a fourth resistor (136) connected between the return (122) of the safety chain (100) and ground (114).

7. The ground fault detector circuit (140) according to claim 6, wherein the fourth resistor (136) is connected between the first resistor (130) and ground (114).

8. The ground fault detector circuit (140) according to claim 1, further comprising a microprocessor for evaluation of the change in voltage drop across the first resistor (130).

9. The ground fault detector circuit (140) according to claim 1, wherein the safety chain (100) includes a safety relay (118) having a coil resistance of 100 Ohm or larger.

10. The ground fault detector circuit (140) according to claim 1, further adapted to carry out a ground fault test continuously over time.

11. The ground fault detector circuit (140) according to claim 1, further adapted to carry out a ground fault test at discrete points in time.

12. The ground fault detector circuit (140) according to claim 1, further adapted to determine a dangerous ground fault in case the change in voltage drop across the first resistor (130) is equal to, or larger, than a first threshold value and to shut-down a power supply of the people conveyor in case a dangerous ground fault is detected.

13. The ground fault detector circuit (140) according to claim 1, further adapted to determine a tolerable ground fault in case the change in voltage drop across the first resistor (130) is equal to, or lower, than a second threshold value.

14. The ground fault detector circuit (140) according to claim 1, further including a power supply unit (112) having a rated power corresponding to nominal voltage times rated current in the safety chain (100).

15. A method for detecting a ground fault (124) in a safety chain (100) of a people conveyor, comprising:
Detecting a change in voltage drop with respect to ground across a first resistor (130) connected between a first contact (P1) on the supply (126) of the safety chain (100) and a second contact (P2) on the return (122) of the safety chain (100).
